(19) United States
(12) Patent Application Publication
(10) Pub. No.: US 2009/0191352 A1
(43) Pub. Date: Jul. 30, 2009

(54) Combustion-Assisted Substrate Deposition Method For Producing Carbon Nanosubstances

(75) Inventors: Douglas P. DuFaux, Orchard Park, NY (US); Randy Vander Wal, Cleveland, OH (US); Masato Tani, Setagaya-ku (JP); Toshiki Goto, Tsuzuki-ku (JP)

Correspondence Address: GREENBERG TRAURIG, LLP, ONE INTERNATIONAL PLACE, 20th FL, ATTN: PATENT ADMINISTRATOR, BOSTON, MA, 02110, US

(73) Assignee: NanoDynamics, Inc.

(21) Appl. No.: 12/019,352

(22) Filed: Jan. 24, 2008

(51) Int. Cl. C23C 4/04; C23C 16/01

(52) U.S. Cl. 427/450; 118/715; 977/742

(57) ABSTRACT

The present invention provides a combustion-based method and apparatus for producing and isolating carbon nanotubes. The nanotubes are formed when hot combustion gases are contacted with a catalytic surface, which is readily separated from the catalyst support and subsequently dissolved. The process is suitable for large-scale manufacture of carbon nanotubes.

### FIELD OF THE INVENTION

The present invention relates generally to methods for producing carbon nanotubes. More particularly, it relates to the production of carbon nanotubes by a combustion process.

### BACKGROUND OF THE INVENTION

Carbon nanotubes (“CNTs”) are widely sought for a variety of applications, including gas storage, absorption, intercalation media, catalyst supports, composite reinforcing materials, electrostatic charge dissipation, electrical conduction, and electromagnetic field shielding. Their advantage lies in both their structure and shape. They have a high aspect ratio and are extremely strong. The atomic level structure is akin to that of graphite; hence the useful electrical, thermal, and mechanical properties. When used as a component of composite materials, the one-dimensional morphology of CNTs permits the use of much lower mass loadings (˜1/10), compared to traditional additives such as carbon black, to realize a given increase in performance.

Although the potential for CNTs is tremendous, the cost of producing pure and uniform samples of CNTs using currently available methods is high, significantly limiting the commercial success of products incorporating such materials.

Currently, four types of technologies are utilized in the synthesis of CNTs, carbon-arc discharge, laser-ablation, carbon vapor deposition processes (“CVD”), and combustion processes.

Using the carbon arc-discharge protocol, CNTs are formed between carbon electrodes in an inert gas atmosphere. Catalytically active additives, e.g., iron and/or cobalt, may be utilized during the arc-discharge process to improve both the productivity and the quality of the CNTs. However, the CNTs produced using this protocol are not pure and contain a mixture of other carbon species, including amorphous and graphitic carbon particles. Purification of the CNTs is difficult, and the final yield of CNTs is low.

The laser-ablation technology applies laser pulses, such as from a Nd:YAG laser, to ablate a target of graphite-metal composite in an inert gas atmosphere maintained at a high temperature, generally between 800-1600° C. However, the cost of CNTs produced using this method is also high. The technology may be suitable for CNT synthesis on a laboratory scale, but it is not suitable for the large-scale production of CNTs required for commercial applications.

A CVD process is powered by heat generated by an external source. In addition to the downstream harvesting and purification issues, the CVD methods are energy intensive, and because the processes are constrained by the confines of an electrically heated vacuum furnace the method is not amenable to continuous operation or commercial-scale production.

Combustion processes involve the formation of CNTs on a solid support, from a hot carbon-rich gas generated by incomplete combustion of a hydrocarbon fuel (R. L. Vander Wal et al., Chem. Phys. Lett. 2000, 323:217-223; R. L. Vander Wal et al., J. Phys. Chem. B 2002, 106:13122-13132; M. J. Height et al., Mat. Res. Soc. Symp. Proc. 2003, 772:M1.8.1). U.S. Patent application publication No. 2003/0133866 also describes a flame-based method for CNT synthesis. CNTs may be formed on catalytic surfaces that favor the formation of nanotubes, but the collection of the nanotubes, especially from high-surface-area substrates designed to produce useful yields, remains difficult and is not amenable to automated large-scale production.

There is a need for an efficient, commercially-scalable production technology that is capable of producing high quality CNTs.

### SUMMARY OF THE INVENTION

The present invention provides a method for producing carbon nanotubes, including but not limited to single-walled carbon nanotubes (“SWNTs”), multi-walled carbon nanotubes (“MWNTs”), and carbon fibers, which comprises the steps of: (a) providing a combustible gas mixture comprising a carbon-containing fuel and an oxygen-containing gas; (b) establishing a flame with said combustible gas mixture, thereby producing a hot post-combustion gas; and (c) contacting the hot post-combustion gas with a solid support having a harvesting layer comprising a catalyst, thereby producing carbon nanotubes on said harvesting layer.

The solid support may consist of any heat-resistant material having suitable mechanical strength to serve as a support for the harvesting layer; suitable materials include but are not limited to ceramics, glasses, and metals.

The harvesting layer is disposed on the surface of the solid support. It comprises one or more catalysts capable of inducing the formation of carbon nanotubes from a hot carbon-containing gas, and further comprises one or more refractory alkali- or acid-soluble metal salts, oxides or hydroxides. The harvesting layer is preferably soluble in an acid or alkali harvesting reagent that does not dissolve the solid support.

Suitable catalysts include but are not limited to transition metals, and salts, oxides, hydroxides, or other compounds or complexes thereof, for example those known in the art to be useful in making carbon nanotubes by the CVD and carbon arc processes.

The carbon-containing fuel is in gaseous form when incorporated into the combustible gas mixture, but may be derived from one or more gaseous, liquid, or solid carbon-containing substances. Particularly suitable carbon-containing fuels are volatile hydrocarbons and oxygenated hydrocarbons.

The combustible gas mixture may further comprise one or more inert gases, such as helium, nitrogen, and argon, and it may further comprise reactive gases such as carbon monoxide and hydrogen.

Practice of the present invention comprises providing a combustible gas mixture as described herein, initiating combustion of the mixture and maintaining the resulting flame by supplying the combustible gas mixture at a suitable rate, and contacting the flame with a supported catalyst and harvesting layer as described herein. This results in the gradual deposition of carbon nanotubes on the harvesting layer. When production of CNTs is at the desired or optimum level, the support is removed from the flame, cooled, and CNTs are harvested by dissolution of the harvesting layer. The solid support may be re-coated with harvesting layer and catalyst and re-used. Unlike prior art methods, the resulting cycle can be incorporated into an automated, continuous process, and carried out on an industrial scale.

### BRIEF DESCRIPTION OF THE FIGURES

FIG. 1 shows a high resolution scanning electron microscope (“HRSEM”) image (scale bar 100 nm) of CNTs produced using an Fe catalyst deposited onto a MgO harvesting layer.

FIG. 2 shows a HRSEM image (scale bar 100 nm) of CNTs produced using a Ni catalyst, where the catalyst was deposited on a MgO harvesting layer.

FIG. 3 shows a HRSEM image (scale bar 100 nm) of CNTs produced using an Fe:Ni catalyst (73.2:26.8, w/w, respectively) deposited on a MgO harvesting layer. Sputtered gold can be seen in the high-resolution image (bottom right).

FIG. 4 shows a HRSEM image (scale bar 100 nm) of CNTs produced using an Fe:Mo catalyst (94.1:5.9, w/w, respectively) deposited onto a MgO harvesting layer.

FIG. 5 shows a HRSEM image (scale bar 100 nm) of CNTs produced using a Co:Mo catalyst (95.9:4.1, w/w, respectively), where the catalyst was deposited on a MgO harvesting layer via a dipping process.

FIG. 6 shows HRTEM image (6a, scale bar 20 nm; 6b, scale bar 5 nm) of CNTs produced using a Co:Mo catalyst (95.9:4.1, w/w, respectively), where the catalyst was deposited on a MgO harvesting layer by impregnation.

FIG. 7 shows the effect of the flame equivalence ratio on the morphology of CNTs produced using an Fe:Ni catalyst. Flame equivalence ratio: (a) 1.62 and (b) 1.73.

FIG. 8 shows HRSEM images of CNTs produced using a Co:Mo catalyst (95.9:4.1, w/w, respectively) impregnated into MgO that had previously been deposited onto a stainless steel 304 mesh substrate.

FIG. 9 shows HRSEM images of CNTs produced using Co:Mo-based catalysts (95.9:4.1, w/w, respectively) where the catalyst was mixed with MgO and then deposited onto a stainless steel 304 mesh substrate.

FIG. 10 presents SEM micrographs illustrating the effects of changing exposure time (the time during which the catalysts were exposed to post-combustion gases). The catalyst composition contained Co:Mo deposited on MgO. Substrates were exposed to post-combustion gases for: (a) 1 minute, (b) 2 minutes, and (c) 5 minutes.

FIG. 11 presents SEM micrographs (scale bar=100 nm) illustrating the effects of changing exposure time of a Ni foil coated with an MgO harvesting layer with a Ni catalyst. Substrates were exposed to post-combustion gases for: (a) 12 minutes and (b) 2 minutes,

FIG. 12 presents SEM micrographs (scale bar=100 nm) illustrating the effects of exposure time on CNT morphology, using an Fe catalyst on a MgO harvesting layer. Substrates were exposed to post-combustion gases for: (a) 1 minute, (b) 2 minutes, and (c) 5 minutes.

FIG. 13 is a plot of the effect of exposure time vs. CNT yield with different catalysts supported on a MgO harvesting layer. Sample A: Co:Mo catalyst (95.9:4.1); Sample B: Ni catalyst; Sample C: Fe catalyst.

FIG. 14 shows a HRSEM image (scale bar=1 μm) of CNTs produced using an Fe catalyst, where the catalyst was deposited onto MgO.

FIG. 15a shows a HRTEM image (scale bar=20 nm) of the CNTs shown in FIG. 20. FIG. 15b (scale bar=5 nm) shows a catalyst particle within a CNT.

FIG. 16 shows a Ni foil at successive processing stages in accordance with one embodiment of the present invention: (a) unprocessed Ni foil; (b) coated with MgO and catalyst; (c) covered with CNTs after exposure to post-combustion gases; (d) after ca. 5 minutes' mild sonication in 2% HNO₃ solution; and (e) suspended CNTs after agitation.

### DETAILED DESCRIPTION OF THE INVENTION

As used herein and in the appended claims, the singular forms “a,” “an,” and “the” should be understood to refer to both singular and plural, unless the context clearly dictates otherwise. Thus, for example, a reference to “a particle” includes a plurality of such particles and equivalents thereof known to those skilled in the art, and a reference to “the catalytically active composition” is a reference to one or more catalytically active compositions and equivalents thereof known to those skilled in the art, and so forth. All publications, patent applications, patents, and other references mentioned herein are incorporated by reference in their entirety.

The present invention provides efficient and cost-effective methods for producing carbon nanotubes. The methods are based on a combustion-assisted substrate deposition process. The term “carbon nanotubes” as used herein and in the appended claims, refers to any composition consisting for the most part of carbon nanotubes, including but not limited to SWNTs, MWNTs, and carbon fibers.

The method for producing carbon nanotubes according to the present invention comprises the steps of: (a) generating a flame with a carbon-containing fuel, thereby producing a hot post-combustion gas; and (b) contacting the hot post-combustion gas with a catalyst disposed upon a solid support. The support preferably has a harvesting layer disposed between the surface of the support and the catalyst. The harvesting layer comprises a nanotube-forming catalyst, so that contact with the hot post-combustion gas produces carbon nanotubes on the harvesting layer. In its simplest embodiments, the process may comprise exposing a supported nanotube-forming catalyst to the hot post-combustion gases generated by combustion of a carbon-containing fuel. In preferred embodiments, the process employs a carbon-containing gas as the fuel, and further comprises the steps of providing a combustible gas mixture comprising a carbon-containing fuel and an oxygen-containing gas, and establishing a flame with said combustible gas mixture, thereby producing a hot post-combustion gas.

### Solid Supports

The solid support may be formed from any heat-resistant material having sufficient mechanical strength to serve as a support for the catalyst and/or harvesting layer; suitable materials include but are not limited to ceramics, glasses, quartz, zeolites, and metals. Although the solid support is preferably durable enough to be re-used after the CNTs are harvested, it may optionally be designed for one-time use. Indeed, it may be acid- or alkali-soluble, and may in certain embodiments be made of essentially the same material as the harvesting layer. In preferred embodiments, the support is durable and is formed from a metal or ceramic. The art of contacting hot flowing gases with supported catalysts is very well-developed, and the various methods currently known may in general be employed in the present invention. The support may take the form of a plate or sheet, either flat or curved into a cylinder, but preferably the support is in a high-surface area form such as a mesh, honeycomb, wool, sponge, or a convoluted foil, or in the form of granules, saddles, Raschig rings, or the like. More preferred are stainless steel and titanium mesh, which may be rolled into cylinders. Particularly preferred as a support is stainless steel mesh.

### Harvesting Layer

The method of the invention preferably employs a harvesting layer, which is a layer of refractory material disposed on the surface of the solid support. It comprises one or more catalysts capable of inducing the formation of carbon nanotubes from a hot carbon-containing gas, and further comprises one or more refractory alkali- or acid-soluble metal salts, oxides or hydroxides. The harvesting layer is formed from a thermally stable material, or from a precursor composition which may be converted to a thermally stable material upon calcining or upon exposure to the reaction conditions of the processes of the present invention.

The precursor composition is typically a slurry or solution of a refractory material, and may optionally incorporate foaming agents or the like, so as to generate a high surface area harvesting layer, and bonding agents as may be necessary to produce a mechanically sound and adherent layer. When the precursor composition is a solution, the concentration of the solution is ordinarily not higher than the saturation concentration, and is usually 0.1 to 60%, and preferably 1 to 40%, by weight. Suitable solvents include water, organic solvents such as lower alcohols (methanol, ethanol etc.), and mixtures thereof. The solvent is preferably water. Any suitable method for application of the solution to the support may be employed; immersion and spray methods are preferred.

A catalytically active composition is applied to or incorporated into the harvesting layer, and may be introduced by adding it to a harvesting layer precursor composition, for example by adding it to a solution or suspension of the refractory material. Alternatively, or in addition, it may be applied to or impregnated into a previously-formed harvesting layer, by methods such as dipping, spraying, CVD, electrochemical deposition, and the like.

The harvesting layer facilitates the collection of CNTs after the reaction is complete. The harvesting layer is preferably readily soluble, which means that it is at least partially soluble in water or in an aqueous acid or alkali harvesting reagent that does not dissolve or undesirably modify carbon nanotubes. “At least partially soluble” in this context means that the harvesting layer is soluble at least to the extent that the carbon nanotubes formed upon it are released from the harvesting layer upon treatment with a harvesting reagent. For example, a layer of glassy silicon dioxide will be dissolved slowly by dilute hydrofluoric acid or hot alkaline sodium hydroxide, and attached carbon nanotubes will thereby be released from the surface, without complete dissolution of the harvesting layer. Such embodiments may be employed to minimize the amount of material that accompanies the released carbon nanotubes. In other embodiments, the harvesting layer will be completely dissolved by the harvesting reagent.

Suitable materials for the harvesting layer are metal salts, oxides, and hydroxides, more preferably the readily-soluble oxides, of silicon, zinc, and alkali and alkaline earth metals. Suitable salts include but are not limited to phosphates, carbonates, silicates, borates, and sulfates. Suitable materials include, but are not limited to, Li₂SiO₃, Na₂SO₄, Na₃PO₄, Al₂O₃, BaO, CaO, MgO, SiO₂, TiO₂, BaCO₂, CaCO₂, MgCO₂, Ba(OH)₂, Ca(OH)₂, Mg(OH)₂, BaPO₄, CaPO₄, MgPO₄, BaSO₄, CaSO₄, and MgSO₄.

Most preferred are oxides and hydroxides of one or more metals selected from the group consisting of Mg, Si, Na, Li, Ca and Zn. Particularly preferred as a harvesting layer are magnesium oxide and lithium silicate. (Metal silicates in this context are considered to be mixed oxides and/or hydroxides of metals and Si.)

Magnesium oxide is particularly suitable as the harvesting layer because (1) it is soluble in mildly acidic solution, so that the removal of magnesium oxide from the support and carbon nanotubes after the reaction does not require exposing the carbon nanotubes to elevated temperatures for an extended period of time; (2) it is catalytically inert; (3) it is an environmentally friendly material; (4) it is relatively non-hazardous and non-toxic; (5) it is readily applied as a slurry; and (6) it forms an adherent and mechanically sound coating on solid supports without addition of bonding agents to the slurry. Although MgO has been employed as a catalyst support in CVD-based synthesis of CNTs, this is the first known application in a combustion environment.

All materials useful as components of the harvesting layer may exist as hydrates to varying degrees, especially when applied in the form of aqueous slurries. It is anticipated that such materials may lose some or all water of hydration upon calcining or upon exposure to the reaction conditions.

In certain embodiments, a catalytically active composition (e.g. nickel nitrate, or a mixture of nickel and molybdenum nitrates) is pre-mixed with the intermediate supporting material (e.g., magnesium oxide or lithium silicate) and the mixture is then applied as a slurry or suspension to the support. For example, a titanium mesh may be coated by dipping it into a suspension of magnesium oxide in a nickel nitrate solution. The resulting coated support is dried and optionally calcined prior to use.

### Harvesting Reagent

The harvesting reagent is preferably water or an aqueous acid or alkali, selected so as to be capable of at least partially dissolving the harvesting layer without damaging or undesirably modifying the solid support or the carbon nanotubes. Most metal oxides are readily soluble in nitric acid, for example, while silicon dioxide and metal silicates are readily soluble in alkali and in hydrofluoric acid. Chelating agents, such as EDTA, and other modifiers such as surfactants, suspending agents, and the like, may be used as components of the harvesting reagent, to facilitate the dissolution of the harvesting layer and/or to reduce the amount of metal impurities in the carbon nanotube product. Preferably, the harvesting reagent does not dissolve the solid support, which will then be re-usable, but in some embodiments the support may be entirely soluble and intended for one-time use.

### Catalysts

The system and methods of the present invention use a solid catalyst composition for catalytically producing carbon nanotubes. The solid catalyst composition contains at least one nanotube-forming catalyst. A nanotube-forming catalyst is a catalyst capable of inducing the formation of carbon nanotubes from a hot carbon-containing gas. Suitable catalysts include but are not limited to transition metals, and salts, oxides, hydroxides, or other compounds or complexes thereof. Zero-valent metals and alloys, in bulk form (e.g. wire, foil, and mesh) or in finely divided form may be used. Preferred catalysts are alloys, salts, oxides, and carbonates of vanadium, cobalt, chromium, molybdenum, manganese, iron, titanium, and nickel. More preferred are catalysts comprising nickel, cobalt, and molybdenum, and particularly preferred is a mixture of nickel and molybdenum, or alternatively cobalt and molybdenum, in a ratio ranging from about 2:1 to about 25:1 w/w on metals basis.

Co, Fe, Mo, and Ni are known as catalysts for CNT synthesis, and each offers unique features desirable for a particular purpose. For example, Fe-based catalysts may be employed to produce graphitic CNTs with relatively few kinks, twists, or coils, while Ni-based catalysts may be utilized to produce CNTs whose walls are composed of relatively short carbon lamella, which generally orient at an angle relative to the tube axis. CNTs produced by Ni generally do have kinks, twists, and coils. Because of these structural differences, the mechanical, electrical, and thermal properties of CNTs produced by Fe-based catalysts are substantially different from those of CNTs produced by Ni-based catalysts. Furthermore, Ni-based catalysts generally have a higher catalytic activity than Fe-based catalysts. The present inventors have found that Ni:Mo and Co:Mo based catalysts appear to be particularly well-suited for use with MgO harvesting layers.

Certain bare metals or alloys (e.g., nickel, stainless steel 304, stainless steel 316, and a Ni—Fe—Mo alloy), upon exposure to hot post-combustion gases, are capable of catalyzing the formation of carbon nanotubes on their surface. These materials do not need surface modification beyond whatever transformations are induced by exposure to the combustion environment, and thus offer the option of avoiding surface treatment and renewal steps, albeit without the ease of isolation provided by a harvesting layer. By way of example, stainless steel 304 mesh, nickel foil, Co:Mo alloy (95.9:4.1, w/w), Fe:Mo alloy (94.1:5.9, w/w), Ni:Mo alloy (90:10, w/w), and Monel™ (Ni—Cu—Co) meshes, may be used as the solid catalyst composition. Other suitable alloys may contain about 70-95% Ni or Co and about 5-30% Mo.

In other embodiments, a catalytically active composition is applied onto a solid support or harvesting layer using standard techniques known in the art, such as dipping, vapor-coating, spray-coating, powder-coating, printing, brushing, and the like. For example, catalyst particles may be deposited onto a stainless steel mesh, nickel foil, or a harvesting layer coated on a solid support, by dipping the support into an aqueous or organic solution of a metal compound, such as a solution containing nickel nitrate, or other salts of nickel, iron, cobalt, and/or molybdenum, and subsequently drying the coated support. Alternatively, the catalyst, in the form of metal particles, nanoparticles, compounds or complexes, may be incorporated into the harvesting layer composition prior to application of the harvesting layer to the solid support. U.S. Patent application publication No. 2005/0074392, incorporated by reference herein, describes suitable methods for impregnating MgO with nanotube-forming catalysts.

The type of metal compounds, the ratio of these metal compounds (e.g., the ratio of Fe:Ni, Co:Mo, or Fe:Ni:Mn), the concentration of the solution, and the type of solvent, may be varied to accommodate a number of factors, such as the type of gaseous carbon-containing fuel composition used and the type of carbon nanotubes desired. For example, iron may be suitable for producing graphitic CNTs with few kinks, twist, or coils. In contrast, nickel may be used for producing CNTs where the walls of the CNTs are composed of relatively short carbon lamella, generally oriented at an angle relative to the tube axis. This type of structure is associated with non-linear morphologies such as kinks, twists, and coils. The mechanical, electrical, and thermal properties of the CNTs produced by nickel may be substantially different from those of the CNTs produced by iron because of such structural differences.

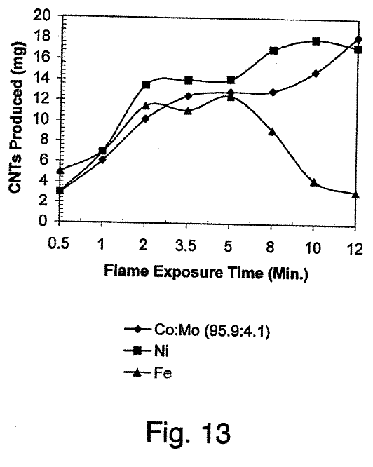

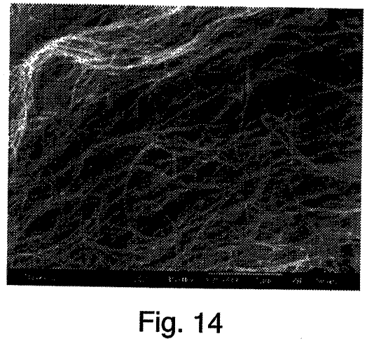

The type of solvent used and the concentration of the salt solution may also affect the type of carbon nanotubes produced by the process of the present invention, because both may substantially influence the morphologies and the distribution of the catalytically active composition on the support material (see, e.g. FIGS. 13 and 14). In one embodiment, the catalytically active composition may be coated to the support using several rounds of impregnation or coating and drying processes. In another embodiment, the size of the catalyst particles may be in sub-micrometer range, for example about 2-5 nm.

### Carbon-Containing Fuel

Generally, the fuel may be any suitable carbon-based fuel, including, without limitation, gaseous carbon-containing fuel compositions (e.g. natural gas), liquid carbon-containing fuel compositions (e.g., naphtha, alcohols, ethers, ketones, esters, aldehydes, aromatic compounds, oils, lipids, kerosene, diesel fuel, and gasoline), and solid carbon-containing fuel compositions (e.g., coal, coke, polymers, lipids, and waxes), or combinations thereof. The fuel is preferably a refined petroleum product or synthetic organic material, so as to minimize catalyst poisoning and contamination of the CNT product. The carbon-containing fuel is in gaseous form when incorporated into a combustible gas mixture, but may be derived from one or more gaseous, liquid, or solid carbon-containing substances. In preferred embodiments, the carbon-containing fuel comprises one or more hydrocarbons or oxygenated hydrocarbon compounds. Suitable compounds include but are not limited to methane, ethane, propane, butane, acetylene, ethylene, methanol, ethanol, benzene, toluene, acetone, and butanone. Unsaturated hydrocarbons are preferred, and particularly preferred fuels comprise ethylene.

Inert or reactive gases may be added to the gaseous fuel composition prior to combustion, to serve as diluents, to control flame temperature, and/or to otherwise influence the yield, purity, or properties of the carbon nanotubes.

### Oxygen-Containing Gas

The oxygen-containing gas may be pure oxygen, and may optionally comprise additional inert or reactive gases, such as helium, nitrogen, argon, carbon monoxide, carbon dioxide, water, and hydrogen. Air may be used, with or without additional modifier gases. As with gases that may be added to the gaseous fuel composition, these modifiers may serve as auxiliary oxidants, auxiliary fuels, and diluents, and may serve to control or modify flame constituents and flame temperature, and/or to otherwise influence the yield, purity, or properties of the carbon nanotubes. Modification of gas compositions to determine their effect on the yield and quality of the carbon nanotubes, and to optimize the yield and quality, is routine and within the ability of those skilled in the art.

Gaseous compositions, such as gaseous carbon-containing fuels, oxygen-containing compositions, and active and inert gases as described above, may also be injected into or otherwise added to the post-combustion gases, for the same purposes.

### Reaction Conditions

In preferred embodiments, the solid catalyst composition is exposed to the flame and/or post-combustion gas at a location (“reaction zone”) where the temperature of the flame or post-combustion gas (“reaction temperature”) is about 480° C. to about 670° C., for a time sufficient to produce the carbon nanotubes. The reaction zone is preferably insulated from the external environment so as to minimize cooling, and thereby maximize the time during which the post-combustion gas is at the reaction temperature. Optionally, additional thermal energy may be added to the reaction zone to counter any cooling effects, for example via radiant heating elements, heating of the solid support, and/or heating coils disposed within the reaction zone. The supported catalyst and harvesting layer are disposed within the flame, and within such regions of the post-combustion gas flow that remain or may be maintained at the reaction temperature, so as to maximize the time during which gases at the reaction temperature are in contact with catalyst. When the post-combustion gas has cooled below the reaction temperature, or when the available carbon nanotube precursors in the post-combustion gas have been effectively exhausted, it may be vented to the atmosphere or routed to a catalytic converter or to an exhaust gas treatment facility for removal of objectionable pollutants.

### Apparatus

The apparatus for maintaining the flame (“combustion means”) may be any combustion device or equipment which is suitable for burning a carbon-containing fuel composition so as to produce a heated post-combustion gas. Combustion devices suitable for the purpose of the present invention are well known in the art. For example, they have been extensively used to produce a variety of materials, including carbon products, of commercial value and a number of combustion-based techniques have evolved as industry standard processes for producing such materials. Each year millions of tons of carbon black, titania, and fumed silica are produced using combustion-based processes.

In particular embodiments, the combustion means may be used to produce, without limitation, diffusion flames (including inverse diffusion flames), pre-mix flames (e.g., partially and completely pre-mix flames), uniform flames, and combinations thereof. The combustion means may be as simple as a Bunsen burner or a common gas torch, but is preferably a device which is capable of producing a large uniform flame from a well-controlled pre-mixed gas mixture, such as a sintered metal burner (e.g., a McKenna burner).

The combustion means may optionally contain a plurality of affiliate systems, such as a flame monitoring and stabilizing system, cooling systems, gas flow regulators, and a nebulizer for liquid fuels. The operation of the combustion means and the affiliate systems are preferably monitored by appropriate sensors and regulated by a computerized control system. In one embodiment, an insulation means, such as a chimney, is provided to the combustion means, where the insulation means at least partially insulates the post-combustion gas from the environment and therefore reduces or minimizes atmospheric gas contamination and heat loss or temperature fluctuation. The insulation means may also provide mechanical support for the catalyst, harvesting layer, and solid support.

The apparatus may optionally include means for pre-heating the gaseous fuel and/or oxygen-containing gases prior to combustion. Control of feed gas flow rates, compositions, and temperatures enable the apparatus to provide a stable and consistent reaction conditions. Provision of a stable environment for the carbon nanotube production reaction, and provision of such an environment as uniformly as possible throughout the reaction volume, enables consistent and reproducible operation under reaction conditions where the controllable parameters are optimized for yield and quality of the CNT product.

The gaseous carbon-containing fuel may be pre-mixed with the oxygen-containing gas before it reaches the combustion means. The flow rate and temperature of the gaseous carbon-containing fuel, and the ratio of the gaseous carbon-containing fuel to the oxygen-containing gas, may be varied as necessary to accommodate a number of factors, such as the particular gaseous carbon-containing fuel composition being employed, the volume of the reaction zone, the type and quantity of catalyst composition used, and the type of carbon nanotube desired.

In the various fields of research that involve the combustion of fuels, a common measurement or variable is the “equivalence ratio”. The equivalence ratio of an air-fuel mixture is a dimensionless number obtained by dividing the actual fuel/oxygen ratio by the fuel/oxygen ratio theoretically required for complete stoichiometric oxidation of the fuel. It is independent of the units used for measurement of the fuel, and independent of whether one employs actual measurements of oxygen or the volume of the oxygen-containing gas. Higher equivalence ratios correspond to richer fuel mixes, and lower ratios accordingly indicate relatively lean mixtures; a ratio of 1.0 corresponds to a mixture with just enough oxygen to oxidize all the fuel present. In preferred embodiments of the present invention, the equivalence ratio of the combustible gas composition is between about 1.4 and about 1.9. In the examples described below, flames based on a pre-mixed ethylene-air combustible gas composition, with equivalence ratios of 1.45, 1.62 and 1.73 are used to produce CNTs.

The inventors have discovered that the thickness, or height, of the solid support may substantially affect the quantity and/or the property of the carbon nanotubes produced using the method of the present invention, as it may be directly proportional to the amount of time the post-combustion gases are in contact with the catalysts. When the height of the solid support in one experiment was increased from about 15 mm to about 30 mm, the yield of CNTs was increased from about 17-18 mg to about 30 mg. However, one cannot increase the length indefinitely. As the post-flame gases interact with the catalysts, and carbon is deposited in the form of CNTs, it is depleted from the gas stream, and ultimately the post-combustion gas becomes inactive with respect to CNT formation. Also, because the temperature is a critical factor in CNT formation, the vertical extent of the zone within which the gases will remain hot enough for CNT formation to occur is limited.

### Continuous Production

The above-described embodiments, and the examples described below, present batch mode methods of operation of the invention. This is suitable for experimental and pilot-plant manufacture of carbon nanotubes, but efficient industrial-scale manufacture (e.g., multi-ton quantities) requires continuous operation to minimize operational costs and equipment down-time. In certain embodiments of the present invention, particularly those designed for large-scale manufacturing, the catalyst-bearing solid surface may be connected to a conveyance means for transporting the catalyst through a reaction zone, where the solid catalyst composition contacts the hot post-combustion gas and catalyzes the production of carbon nanotubes on the surface. A plurality of catalyst-bearing objects, which may be the solid supports of the invention or may carry the solid supports of the invention, may be removably connected with the conveyor by appropriate means for holding or otherwise supporting the objects while they are transported through the reaction zone. Conveyance means for carrying objects through a high temperature zone are well-known to those skilled in the art; suitable examples include but are not limited to conveyor belts, chains, rollers, tracks, and the like.

The conveyance system may optionally transport the solid supports through a pre-heating zone, where the supports and catalysts are heated to a temperature close to that of the reaction zone, prior to transporting the coated objects into the reaction zone where carbon nanotubes are synthesized on the surface of the objects. This may serve to limit cooling of the post-combustion gases and maintain uniform temperatures in the reaction zone, and a uniform temperature of the catalyst and solid surface throughout the reaction period. By controlling the speed of the conveyor and/or the length of the path through the reaction zone, the duration of the carbon nanotube synthesis reactions may be controlled so that a desirable amount of carbon nanotubes may be formed on the surface of each of the objects.

Using this mechanism, carbon nanotubes may be formed directly on surfaces where it is desirable to apply a coating of carbon nanotubes, eliminating the time and expense associated with collection and purification. Furthermore, this mechanism enables a continuous manufacturing of carbon nanotubes and nanotube-coated objects, a capacity not provided by the batch-mode carbon nanotube manufacturing technologies currently known in the art.

In certain embodiments, the conveyor may itself be the solid support. For example, an endless chain or belt may be formed from wire, mesh, woven fabric, or links of stainless steel, titanium, Ni—Mo alloy, or the like, and the belt or chain transported continuously through zones for catalyst and/or harvesting layer application, calcining, pre-heating, nanotube synthesis, cooling, and nanotube harvesting.

The duration of the carbon nanotube synthesis reaction, and the residence time in the reaction zone, varies according to a number of factors, such as the reaction temperature, the type of catalyst and the gaseous carbon-containing fuels used, the equivalence ratio of the combustion gas, the type and amount of carbon nanotube desired, and the speed of the conveyor. The reaction temperature may be any temperature from about 400° C. to about 1000° C. As in batch mode operation, preferred reaction temperatures range from about 450° C. to about 800° C., and more preferably from about 480° C. to about 670° C. The inventors have observed the onset of CNT growth within 0.1-30 seconds of exposing the solid catalyst composition to the post-combustion gases. Typically, the exposure of the solid catalyst composition to the post-combustion gases, i.e., the duration of the synthesis reaction, may be between about 0.1 seconds and 150 minutes, or between about 1 and 20 minutes, or between about 5 and 15 minutes.

In another aspect, the present invention provides a method for producing and substantially simultaneously purifying carbon nanotubes. Without being bound by theory, the inventors believe that the amorphous carbon species that commonly contaminate prior art nanotube preparations are oxidized under the specific reaction conditions of the present invention, and accordingly are not deposited on the catalytic surfaces of the solid support. Thus, the carbon nanotubes as formed are substantially free from amorphous carbon species. By virtue of the readily-soluble harvesting layer, the carbon nanotubes are also largely free of catalytic transition metals. In preferred embodiments, the carbon nanotubes produced using the method of the present invention are substantially free from amorphous carbon species (e.g., soot) and are also substantially free of the catalytically active species of the solid catalyst composition (e.g., metals such as nickel, iron, and molybdenum).

In preferred embodiments, the combustible gas composition comprises at least one oxidant, a pre-mixed gaseous carbon-containing fuel, and optionally other active or inert gases (e.g., H₂ and N₂). The primary oxidant is oxygen, which may be supplemented any mild oxidant known in the art which is suitable for oxidizing amorphous carbon materials under the reaction conditions of the present invention, such as water vapor and carbon dioxide. The pre-mixed carbon-containing fuel may include, without limitation, carbon monoxide, methane, ethane, ethylene, and acetylene, and mixtures thereof. The ratio of the carbon-containing gases in the mixture may be varied according to the type of gases used, the reaction temperature, the catalyst, the type of carbon nanotubes desired, and the equivalence ratio desired, and may be determined empirically or using techniques known in the art (e.g. via the STANJAN code). For example, mixtures of H₂, CO, H₂O, CO₂, and CH₄ with molar ratios of 780:370:530:130:350, 770:330:590:130:270, or 730:260:700:130:160, may be used for the production of carbon nanotubes.

It may be necessary to adjust the temperature of the gaseous carbon-containing composition and/or the solid catalyst composition to a temperature suitable for catalytically converting carbon-containing gases to carbon nanotubes while substantially simultaneously oxidizing or preventing deposition of amorphous carbon species produced during the process. In one embodiment, the pre-mixed oxidant and carbon-containing gases may be pre-heated to the reaction temperature before reaching the solid catalyst composition. In another embodiment, the temperature of the solid catalyst composition may be maintained (e.g., through using a heating and/or cooling system) at the reaction temperature. In yet another embodiment, the temperature of a post-combustion gas is adjusted, e.g., using a cooling system, to the reaction temperature. The reaction temperature may be varied according to the types of catalyst and gaseous carbon-containing composition used. For example, when a post-combustion gas is used as the gaseous carbon-containing composition, the reaction temperature may be at about 480° C. to about 670° C. or higher.

The carbon nanotubes produced by the processes of the present invention may be harvested by mechanical disruption of the harvesting layer (e.g. by scraping, flexing, or vibrating the solid support, and/or by scouring the solid support with a jet of air, water, or other fluid). They may also be harvested by directly contacting the solid support, which carries the harvesting layer and the CNTs produced during the reaction, with a harvesting reagent, optionally with sonication, for at least a period of time sufficient to separate the nanotubes from the solid support. Harvesting layer material that has been mechanically-disrupted and removed from the solid support may likewise be treated with a harvesting reagent, optionally with sonication, to dissolve the harvesting layer and leave the intact carbon nanotubes in suspension.

As an example, when a coating of MgO is used as the harvesting layer, suitable acidic solutions include but are not limited to about 0.1-20% or about 1-10% nitric acid solutions, and similar concentrations of perchloric acid. These acids efficiently dissolve MgO, and the dissolution process is accelerated with sonication. The time required typically ranges from about 10 seconds to about 10 minutes, depending on the acid or alkali concentration, the density and thickness of the MgO layer, and the sonication power The harvested carbon nanotubes may then be isolated from the acidic solution by standard methods, including but not limited to filtration and centrifugation, washed with water and/or organic solvents, and optionally further dried in air, inert gas, or vacuum. Wet nanotubes may also be re-dispersed in a solvent and the resulting dispersion or suspension stored, distributed, and marketed as such.

### EXAMPLES

The following examples illustrate the present invention, and are set forth to aid in the understanding of the invention. They are not intended to, and should not be construed to, be limiting in any way to the scope of the invention as set forth in the claims.

### Example 1

### Laboratory Scale Synthesis

A titanium sheet having a thickness of 0.1 mm was formed into a cylinder having a diameter of 50 mm and a height of 15 mm. The cylinder was immersed in a 40 wt % aqueous solution of lithium silicate for about 1 minute, taken out, and dried at 120° C. for 1 hour, to form a lithium silicate film on the substrate.

The coated substrate was then immersed in a 5% by weight aqueous nickel nitrate solution for about 10 minutes, taken out, dried 120° C., and annealed at 600° C. for about 1 hour to generate a catalyst-bearing harvesting layer on the titanium support.

A premixed combustible gas composition consisting of ethylene and air was introduced into a burner, and this was ignited to generate a flame. The coated titanium cylinder was inserted and left in contact with the flame for 12 minutes. A black substance was produced on the substrate surface. Observation of the black substance with a scanning electron microscope revealed that it consisted essentially of carbon nanotubes having a diameter of around 20 to 30 nm.

The substrate was immersed in a 1.0 N aqueous sodium hydroxide solution maintained at 50° C. After 1 hour, the black product had completely separated from the substrate, and a dispersion of carbon nanotubes was obtained. The dispersion was filtered and the solids washed with water and dried at 120° C., to provide 20 mg of carbon nanotubes.

### Example 2

### Pilot Scale Combustion System

Primary system components included a burner, a mounting plate, an electrical/control panel, a computer control station, gas supply tanks and automatic switch-over feed manifolds, a gas control panel, and a water cooling system. The burner and the mounting plate were housed in a 1 meter×1.3 meter exhausted section of the system.

The system included a computer control station, which was a standard PC running control and data acquisition/logging software (LabView™ 7, National Instruments Inc.) Gas flow was controlled by mass flow controllers and a dedicated control processor that was integrated into the LabView™ software. Automatic switch-over feed manifolds allowed continuous operation by sensing and switching from empty to full gas supply tanks, and empty tanks could be changed without interrupting the operation. Electrical controls ensured safe operation by interlocking several key variables, including hood pressure (exhaust flow), internal temperature of the burner (overheating), and system power (power failures).

Pre-mixed flames were established and stabilized on a water-cooled, stainless steel sintered metal burner. The burner, commonly referred to as a McKenna or “flat-flame” burner, contained a sintered metal disk surrounded by a sintered metal annulus. For small-scale CNT production, a burner having a diameter of 60 mm and a 5 mm annular ring was used.

Experiments described in the examples were conducted using ethylene-air premixed flames issuing from the primary section of the burner. The airflow rate was maintained at 11.5 standard liters per minute (SLPM) while the fuel flow was adjusted to achieve the desired equivalence ratio. The present invention employs a flame that is relatively oxygen-poor. Equivalence ratios ranging from 1.45 to 1.73 were employed in the examples described herein, but other ratios can be employed and are within the scope of the invention. Although commercially available industrial-grade fuels are expected to lead to an acceptable product, research quality (99.95% purity) fuels were utilized in these experiments, due to their ready availability (relative to industrial-grade fuels) in research quantities.

A cylindrical chimney was employed in the experiments. The chimney served several purposes, including: (1) confinement of post-combustion gases and reduction of atmospheric gas contamination otherwise created by cross-flow room currents, (2) supplying a support to the catalyst, and (3) minimizing heat loss and temperature fluctuation, which was the most important aspect of the chimney design. Flame temperature measurements with an exposed type R fine-bead thermocouple indicated that there was an approximately 300° C. variation in gas temperature, measured radially from the center of the chimney to the wall, at relevant distances above the burner. For equivalence ratios of 1.62 and 1.73, temperatures of approximately 500° C. near the wall and 800° C. near the center were observed. During production runs, carbon nanotube growth was observed to occur primarily at cooler locations near the wall.

To estimate the post-flame gas composition, the STANJAN equilibrium code was employed. Calculations were based on the measured post-flame gas temperature and the equivalence ratio. Table 1 shows the results of the computations.

TABLE 1
Stanjan Thermodynamic Equilibrium Code Calculations

| Fuel/Air | Adiabatic | Local | Equilibrium Post-Flame Gas Composition | | | | |
|---|---|---|---|---|---|---|---|
| Equivalence | Flame Temp. | Temperature | (Mole Fraction) at Local Temperature* | | | | |
| Ratio | (° C.) | (° C.) | H₂ | CO | H₂O | CO₂ | CH₄ |
| 1.73 | 1781 | Adiabatic | 0.0882 | 0.153 | 0.102 | 0.0372 | — |
| | | 800 | 0.123 | 0.119 | 0.0675 | 0.0713 | 0.00002 |
| | | 500 | 0.0785 | 0.0372 | 0.0536 | 0.131 | 0.0357 |
| 1.62 | 1850 | Adiabatic | 0.0708 | 0.139 | 0.111 | 0.0439 | — |
| | | 800 | 0.107 | 0.103 | 0.0757 | 0.0794 | 0.00001 |
| | | 500 | 0.0776 | 0.0333 | 0.0597 | 0.132 | 0.0277 |
| 1.45 | 1958 | Adiabatic | 0.0450 | 0.111 | 0.122 | 0.0573 | — |
| | | 800 | 0.0807 | 0.0771 | 0.0890 | 0.0926 | 0.000003 |
| | | 500 | 0.0731 | 0.0267 | 0.0705 | 0.133 | 0.0158 |

*Analysized species were restricted to: C, CH₄, CO, CO₂, C₂H₂, C₂H₄, H radical, H₂, H₂O, N₂, and O₂. The temperature of the feed gas is about 300° K. The concentration of H radicals at adiabatic flame conditions was on the order of 10⁻⁴, and the balance is primarily N₂. The concentrations of other species were negligible (less than 10⁻⁸ mole fraction).

Three types of solid catalyst systems were used: (1) bare metals and alloys, (2) metals and non-metals coated with inert materials as harvesting layers, then coated with catalyst particles; and (3) alloys coated with catalyst particles mixed with inert materials. The solid supports employed are shown in Table 2.

TABLE 2
Substrate materials

| Bare Metals/Alloys | Separate Coatings | Mixed Coatings |
|---|---|---|
| Nickel Foil | Nickel Foil | Stainless Steel |
| | | 304 Mesh* |
| Nickel Mesh | Nickel Mesh | |
| Monel ™ Mesh | Monel ™ Mesh | |
| Stainless Steel | Stainless Steel 304 Mesh* | |
| 304 Mesh* | | |
| Stainless Steel | Stainless Steel 316 Mesh | |
| 316 Mesh | | |
| | Carbon Fiber Mat | |

*Two types of stainless steel 304 mesh were employed, with 0.0021 and 0.0016 inch wire diameters.

For bare metals and alloys, catalyst particles are formed from the mesh itself, upon immersion within the flame gases, through various vapor and solid-state reactions (e.g., carbide reactions). Coated materials, on the other hand, rely on catalyst particles formed during the preparation of the catalyst composition. For example, small catalyst particles were applied to the support by dipping the support in a solution containing an active catalyst material (e.g., nickel nitrate) and subsequently drying the coated support. These particles, presumably nickel nitrate crystals, become catalytically active when exposed to flame gases.

Magnesium oxide (MgO) was used as an inert intermediate supporting material and served as a harvesting layer. In a number of experiments where MgO harvesting layers were employed, catalysts were first deposited onto or pre-mixed with MgO as metal salts (e.g., nickel nitrate), and the catalyst particles were formed through decomposition of the salts during the process or by calcination. A list of catalysts and processing solutions are shown in Table 3.

TABLE 3
Catalyst materials

| | Mass Ratio | | |
|---|---|---|---|
| Catalyst(s) | (w/w) | Precursor(s) | Solvent |
| Ni | N/A | Nitrate | DI Water; EtOH |
| Fe | N/A | Nitrate | DI water, EtOH |
| Mo | N/A | Nitrate | DI water, EtOH |
| Ni:Fe | 59.4:40.6 | Nitrates, Chlorides | DI water; EtOH |
| Ni:Fe | 26.8:73.2 | Nitrates, Chlorides, | DI water |
| | | environmental solution | |
| Ni:Fe | 92.9:7.1 | Nitrates, Chlorides, | DI water |
| | | environmental solution | |
| Fe:Mo | 94.1:5.9 | Nitrate | DI water, EtOH |
| Co:Mo | 95.9:4.1 | Nitrate, | DI water |
| | | environmental solution | |
| Fe:Ni:Cr:Mn | stainless steel | Nitrate | DI water |
| | 304 ratio* | | |

*A catalyst with a metallic composition equivalent to that of 304 stainless steel was formulated and incorporated onto/into the MgO via either impregnation or pre-mixing processes.

Production results were analyzed using several methods. First, substrates were visually inspected for CNT growth. Black areas indicated CNT growth. Although such coloration could indicate other carbonaceous deposits, this was not generally observed, and the CNTs produced using the method of the present invention generally are substantially free from amorphous carbon species. Thus, coloration was an excellent preliminary visual indicator of CNT growth, and could be used to determine the onset of CNT growth. Such observations showed the onset of significant CNT growth in as little as 15-30 seconds. Other analyses were primarily based on high resolution scanning electron microscopy (HRSEM) and transmission electron microscopy (TEM). HRSEM was especially suitable for examining the morphology of CNTs because the technique is capable of reflecting the structural features of freshly-made, unprocessed CNTs. This capacity is desirable because, as a number of studies have shown, processing, including, for example, a washing with water, can cause structural changes. TEM was used to verify that CNTs were successfully produced, as opposed to other carbon species such as nanofibers and whiskers. Detailed analysis of the structural quality of the CNTs was obtained with High Resolution TEM (HRTEM).

Substrates were exposed directly (i.e. without catalysts) to post-flame gases to evaluate possible spontaneous catalytic activity and to check for non-CNT carbonaceous deposits such as soot. At the three equivalence ratios employed, no indications of soot or other non-CNT carbonaceous deposits were found on the substrates tested. Generally, metal and alloy meshes showed some catalytic activity, but growth density and yield varied greatly—from very little, patchy growth, to high-density growth, depending on the substrate and the equivalence ratio. Three types of stainless steel mesh were tested: two of type 304 and one of type 316. Type 304 stainless steel wire mesh, and nickel foil and foam substrates, proved to be effective catalysts for CNT growth.

Various supports were coated with catalysts and harvesting layers to facilitate the collection of the CNTs produced. Three methods are exemplified in this application: (1) coating substrates with MgO and calcining, followed by dipping the MgO-coated structure into a catalyst solution and calcining again; (2) pre-mixing of the catalyst with the MgO, coating the mesh support by dipping, and then calcining, and (3) dipping the substrate into a solution of lithium silicate and drying at 120° C. for 1 hour, then immersing in an aqueous catalyst solution.

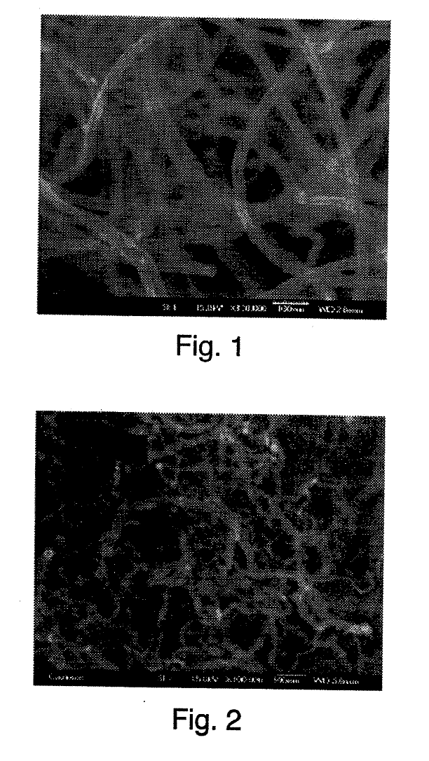

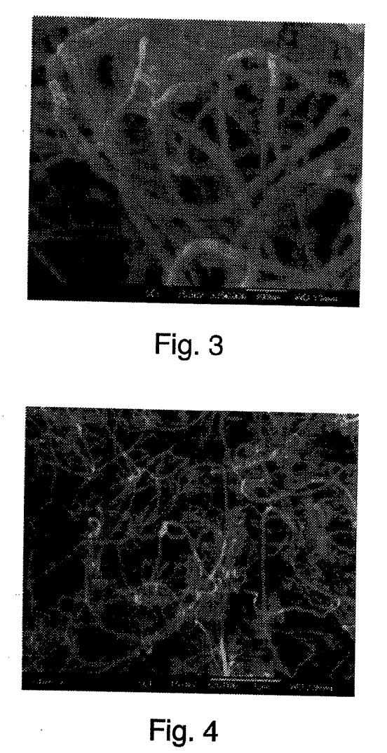

The performance of Fe, Ni, and Ni:Fe (26.8:73.2, w/w) catalysts were tested. Each produced CNTs with a characteristic morphology, as shown in FIGS. 1-3. FIG. 1 shows CNTs synthesized with Fe catalysts, with long, relatively well organized structure. CNTs grown with Ni catalysts (FIG. 2), show poorly organized tubes, with numerous kinks.

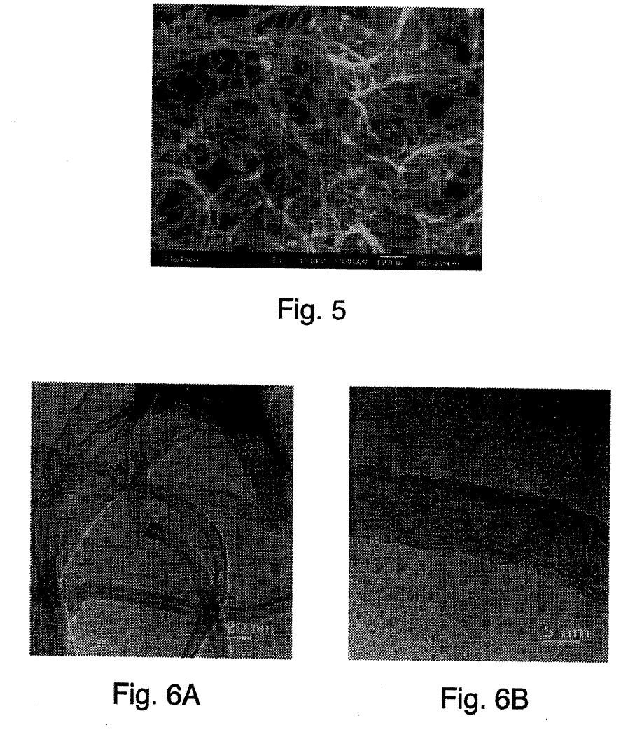

FIGS. 5 and 6 are HRSEM and HRTEM images of CNTs produced using a Co:Mo catalyst (95.9:4.1, w/w). HRTEM images show that the products are graphitic multi-walled CNTs. The lower magnification HRTEM image, as well as the HRSEM images, illustrate that the CNTs are relatively uniform in terms of size and morphology. Notably there is an absence of extraneous carbonaceous material or pyrolytic carbon on the exterior surfaces of the MWNTs.

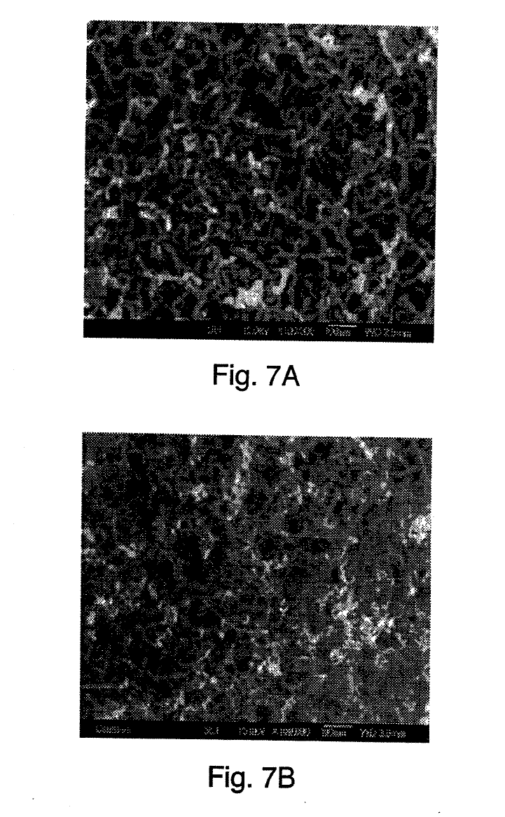

The effects of flame chemistry on the production of CNTs was investigated. In general, an equivalence ratio of 1.73 was more effective at producing CNTs, under a variety of experimental conditions used, when compared to equivalence ratios of 1.62 and 1.45 (FIG. 7).

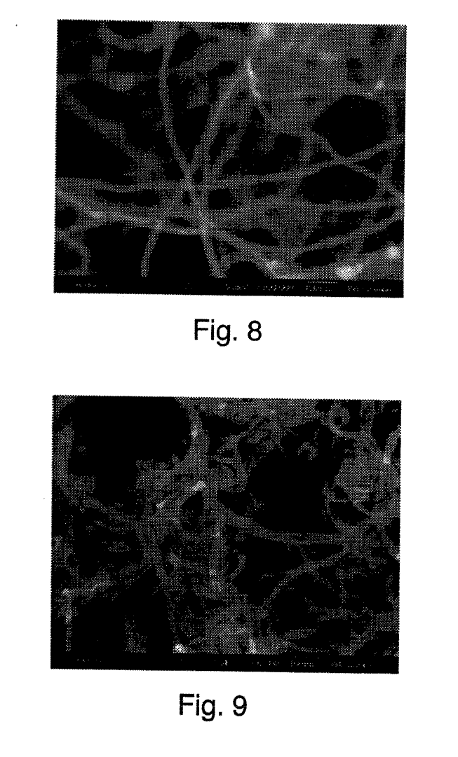

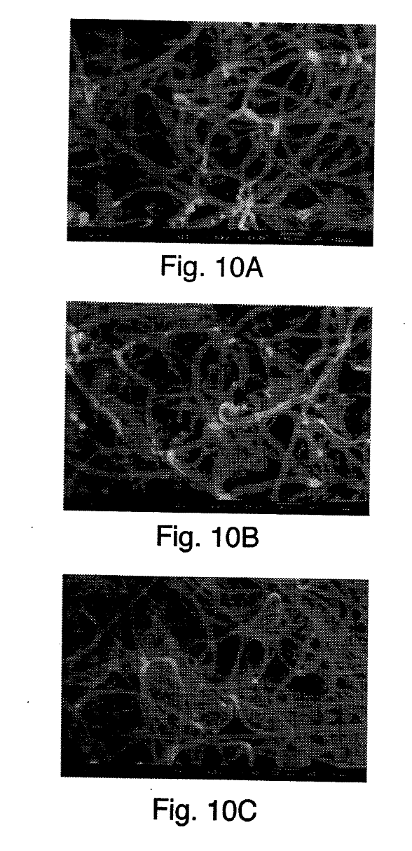

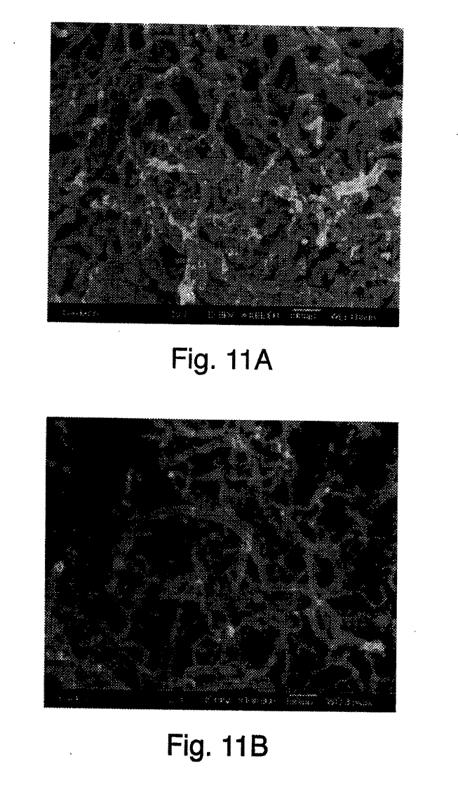

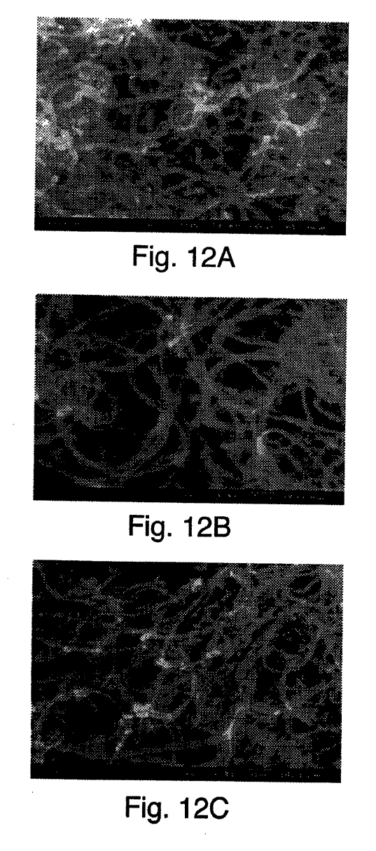

The effects of different coating protocols were studied. FIGS. 8 and 9 illustrate CNTs produced by Co:Mo catalysts on stainless steel 304 mesh substrates. The catalyst composition used to produce CNTs shown in FIG. 8 was prepared by first coating a stainless steel 304 mesh substrate with MgO and calcining the coated substrate, followed by impregnation with the catalyst by dipping the MgO-coated structure into a solution containing the catalyst. The catalyst composition used to produce CNTs shown in FIG. 7 was prepared by pre-mixing the Co:Mo catalyst with MgO prior to deposition upon the mesh, followed by calcining. Although the morphology of the resulting CNTs was similar, there was a distinct difference in how the tubes were intermingled.

The effects of the exposure time, i.e., the duration of contact of a catalyst with post-combustion gases, were also investigated. The data show that yields vary with flame exposure, but not in a consistent manner from one catalyst to the next. The results are shown in FIG. 13, where the relative yield is calculated based on the yield at 12 minutes.

The height of the substrate is an important design parameter, as it is directly proportional to the amount of time the post-flame gases are in contact with the substrate. In the present study, when the height of the substrate was doubled from approximately 15 to 30 mm, there was an approximately 2-fold increase in the yield of CNTs.

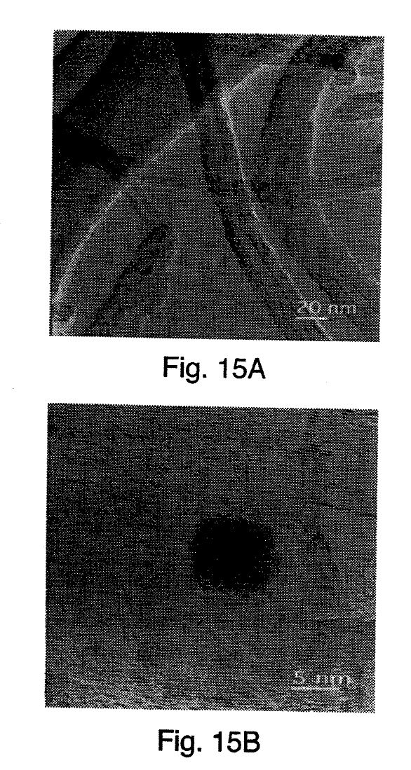

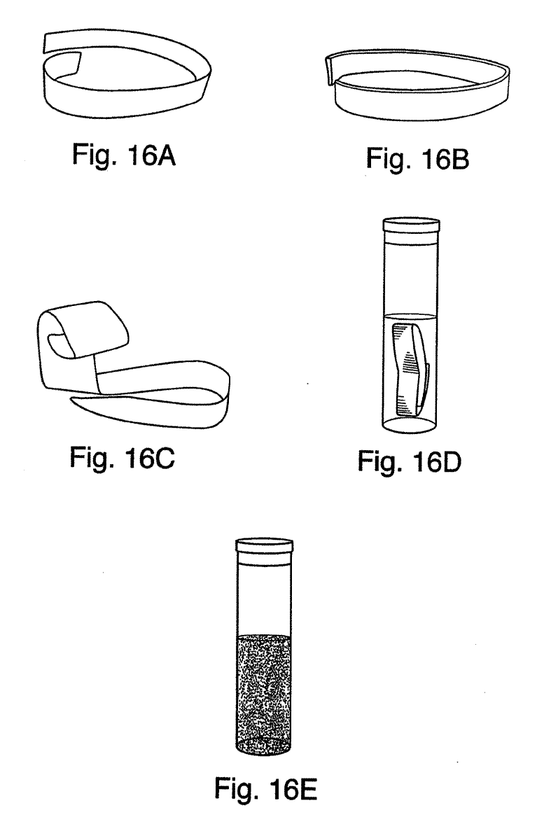

Two harvesting methods were compared: (1) acid washing in a mild ultrasonic bath, and (2) mechanical scraping. FIG. 15 shows a series of photographic images of a Ni foil substrate. FIG. 15(a) depicts a bare Ni foil; FIG. 15(b) shows the Ni foil coated with MgO and catalysts; and FIG. 15(c) shows the substrate after exposure to post-combustion, gases. Several such CNT-covered samples were soaked in nitric acid (2% or 15%) in a mild ultrasonic bath for 2-10 minutes to remove CNTs and MgO coating. FIG. 16 illustrates typical results of the acid treatment. The free CNTs could be isolated from the acid solution by filtering or centrifugation. To evaluate the potential of using mechanical scraping techniques, a sample similar to that shown in FIG. 15 was scraped with a stainless steel razor. Although this removed the majority of CNTs from the metal, quantitative removal, or removal from non-planar high-surface-area supports, would clearly be difficult.

What is claimed is:

1. A method for producing carbon nanotubes, comprising the steps of:
(a) establishing a flame with a carbon-containing fuel and an oxygen-containing gas, thereby producing a hot post-combustion gas; and
(b) contacting the hot post-combustion gas with the surface of a harvesting layer comprising a nanotube-forming catalyst thereby producing carbon nanotubes on said surface.

2. The method of claim 1, wherein the harvesting layer comprises a readily-soluble metal salt, oxide or hydroxide.

3. A method for producing carbon nanotubes, comprising the steps of:
(a) providing a combustible gas mixture comprising a carbon-containing fuel and an oxygen-containing gas;
(c) establishing a flame with said combustible gas mixture, thereby producing a hot post-combustion gas; and
(d) contacting the hot post-combustion gas with the surface of a harvesting layer comprising a nanotube-forming catalyst, thereby producing carbon nanotubes on said surface.

4. The method of claim 3, wherein the harvesting layer comprises a readily-soluble metal salt, oxide or hydroxide.

5. The method of claim 4 wherein the harvesting layer comprises a readily-soluble material selected from the group consisting of readily-soluble metal oxides, metal carbonates, metal sulfates, metal phosphates, and metal hydroxides.

6. The method of claim 5, wherein the harvesting layer comprises a readily-soluble oxide or hydroxide of silicon, zinc, an alkali metal, or an alkaline earth metal.

7. The method of claim 6, wherein the harvesting layer comprises magnesium oxide or lithium silicate.

8. The method of claim 4, wherein the harvesting layer is disposed on the surface of a solid support, wherein said harvesting layer consists essentially of a readily-soluble metal salt, oxide, or hydroxide.

9. The method of claim 8, wherein the harvesting layer consists essentially of a readily-soluble material selected from the group consisting of metal oxides, metal carbonates, metal sulfates, metal phosphates, and metal hydroxides.

10. The method of claim 9, wherein the readily-soluble material is an oxide or hydroxide of silicon, zinc, an alkali metal, or an alkaline earth metal.

11. The method of claim 10, wherein the readily-soluble material is magnesium oxide or lithium silicate.

12. The method claim 3, wherein the catalyst comprises at least one metal selected from the group consisting of Ni, Mo, Co, Cr, Fe, Ti, and V.

14. The method of claim 12, wherein the catalyst comprises Co and Ni.

15. The method of any claim 4, wherein the temperature of the post-combustion gas in contact with the solid surface is between about 480° C. and about 670° C.

16. The method claim 3, further comprising the step of treating the harvesting layer with a harvesting reagent so as to separate the carbon nanotubes from the harvesting layer.

17. The method of claim 11, wherein the readily-soluble material is magnesium oxide, and further comprising the step of treating the solid support with aqueous nitric acid so as to separate the carbon nanotubes from the support.

18. The method of claim 11, wherein the readily-soluble material is lithium silicate, and further comprising the step of treating the solid support with aqueous sodium hydroxide so as to separate the carbon nanotubes from the support.

19. An apparatus for the manufacture of carbon nanotubes, comprising:
(a) a first gas inlet for introducing an oxygen-containing gas composition;
(b) a second gas inlet for introducing a gaseous carbon-containing fuel composition;
(c) a mixing chamber in communication with said first ad second inlets, for combining the oxygen-containing gas composition and the gaseous carbon-containing fuel composition so as to generate a combustible gas mixture;
(d) a burner in communication with said mixing chamber, for maintaining a flame in which the combustible gas mixture is converted into a hot post-combustion gas; and
(e) a solid support disposed on the flame side of said burner, in the region occupied by the flame and hot post-combustion gas;
wherein the surface of said solid support comprises a harvesting layer and a carbon nanotube-forming catalyst.

20. The apparatus of claim 19, further comprising an insulation means for at least partially isolating the hot-post combustion gas from the environment.

21. The apparatus of claim 20, further comprising a conveyance means for transporting the solid support into and out of the region occupied by the flame and post-combustion gas.

22. The method of claim 2 wherein the harvesting layer comprises a readily-soluble material selected from the group consisting of readily-soluble metal oxides, metal carbonates, metal sulfates, metal phosphates, and metal hydroxides.

23. The method of claim 22, wherein the harvesting layer comprises a readily-soluble oxide or hydroxide of silicon, zinc, an alkali metal, or an alkaline earth metal.

24. The method of claim 23, wherein the harvesting layer comprises magnesium oxide or lithium silicate.

25. The method of claim 2, wherein the harvesting layer is disposed on the surface of a solid support, wherein said harvesting layer consists essentially of a readily-soluble metal salt, oxide, or hydroxide.

26. The method of claim 25, wherein the harvesting layer consists essentially of a readily-soluble material selected from the group consisting of metal oxides, metal carbonates, metal sulfates, metal phosphates, and metal hydroxides.

27. The method of claim 26, wherein the readily-soluble material is an oxide or hydroxide of silicon, zinc, an alkali metal, or an alkaline earth metal.

28. The method of claim 27, wherein the readily-soluble material is magnesium oxide or lithium silicate.

29. The method of claim 1, wherein the catalyst comprises at least one metal selected from the group consisting of Ni, Mo, Co, Cr, Fe, Ti, and V.

30. The method of claim 29, wherein the catalyst comprises Co and Ni.

31. The method of claim 2, wherein the temperature of the post-combustion gas in contact with the solid surface is between about 480° C. and about 670° C.

32. The method of claim 1, further comprising the step of treating the harvesting layer with a harvesting reagent so as to separate the carbon nanotubes from the harvesting layer.

33. The method of claim 28, wherein the readily-soluble material is magnesium oxide, and further comprising the step of treating the solid support with aqueous nitric acid so as to separate the carbon nanotubes from the support.

34. The method of claim 28, wherein the readily-soluble material is lithium silicate, and further comprising the step of treating the solid support with aqueous sodium hydroxide so as to separate the carbon nanotubes from the support.
